(19) United States
(12) Patent Application Publication
(10) Pub. No.: US 2024/0153977 A1
(43) Pub. Date: May 9, 2024

(54) SOLID-STATE IMAGING DEVICE

(71) Applicant: TOPPAN Inc., Tokyo (JP)

(72) Inventor: Koei OTSUKA, Taito-ku (JP)

(73) Assignee: TOPPAN Inc., Tokyo (JP)

(21) Appl. No.: 18/413,192

(22) Filed: Jan. 16, 2024

Related U.S. Application Data
(63) Continuation of application No. PCT/JP2022/027879, filed on Jul. 15, 2022.

(30) Foreign Application Priority Data
Jul. 21, 2021 (JP) 2021-120749

(51) Int. Cl. H01L 27/146

(52) U.S. Cl. CPC H01L 27/14627; H01L 27/14621

(57) ABSTRACT

A solid-state imaging device includes a wafer substrate having photoelectric conversion elements, a filter part formed on the wafer substrate and having color filters positioned in correspondence with the photoelectric conversion elements, and a microlens part including a non-photosensitive resin and having microlenses positioned in correspondence with the color filters. The microlenses are positioned with a gap between two microlenses adjacent to each other in a diagonal direction of a square region in which the color filters are positioned and with a gap between two microlenses adjacent to each other in a direction in which a side of the square region extends.

### CROSS-REFERENCE TO RELATED APPLICATIONS

The present application is a continuation of and claims the benefit of priority to International Application No. PCT/JP2022/027879, filed Jul. 15, 2022, which is based upon and claims the benefit of priority to Japanese Application No. 2021-120749, filed Jul. 21, 2021. The entire contents of these applications are incorporated herein by reference.

### BACKGROUND OF THE INVENTION

### Field of the Invention

The present invention relates to a solid-state imaging device, and more specifically to an on-chip solid-state imaging device to which a color filter and a microlens array are attached.

### Description of Background Art

For example, JP 2013-8777 A describes an on-chip solid-state imaging device having microlenses. The entire contents of this publication are incorporated herein by reference.

### SUMMARY OF THE INVENTION

According to one aspect of the present invention, a solid-state imaging device includes a wafer substrate having photoelectric conversion elements, a filter part formed on the wafer substrate and having color filters positioned in correspondence with the photoelectric conversion elements, and a microlens part including a non-photosensitive resin and having microlenses positioned in correspondence with the color filters. The color filters are positioned in a square region, and the microlenses are positioned such that two microlenses adjacent in a diagonal direction of the square region form a diagonal gap extending between the two microlenses adjacent in the diagonal direction of the square region and that two microlenses adjacent in a side direction of the square region form a horizontal gap extending between the two adjacent microlenses adjacent in the side direction of the square region.

According to another aspect of the present invention, a solid-state imaging device includes a wafer substrate having photoelectric conversion elements, a filter part formed on the wafer substrate and having color filters positioned in correspondence with the photoelectric conversion elements, and a microlens part including a non-photosensitive resin and having microlenses positioned in correspondence with the color filters. The color filters are positioned in a square region, and the microlens part is formed such that the microlenses have a fill factor in a range of 65% to 75%, where the fill factor is a ratio of an area of a region of the microlenses to an area of the square region of the color filters.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a schematic cross-sectional view of a solid-state imaging device according to an embodiment of the present invention;

FIG. 2 is an image showing a conventional microlens part in plan view;

FIG. 3 is a diagram for describing gaps between microlenses;

FIG. 4 is a diagram illustrating a process of manufacturing a solid-state imaging device according to an embodiment of the present invention;

FIG. 5 is a diagram illustrating a process of manufacturing a solid-state imaging device according to an embodiment of the present invention;

FIG. 6 is a diagram illustrating a process of manufacturing a solid-state imaging device according to an embodiment of the present invention; and

FIG. 7 is an image of a microlens part of a produced solid-state imaging device in plan view according to an embodiment of the present invention.

### DETAILED DESCRIPTION OF THE EMBODIMENTS

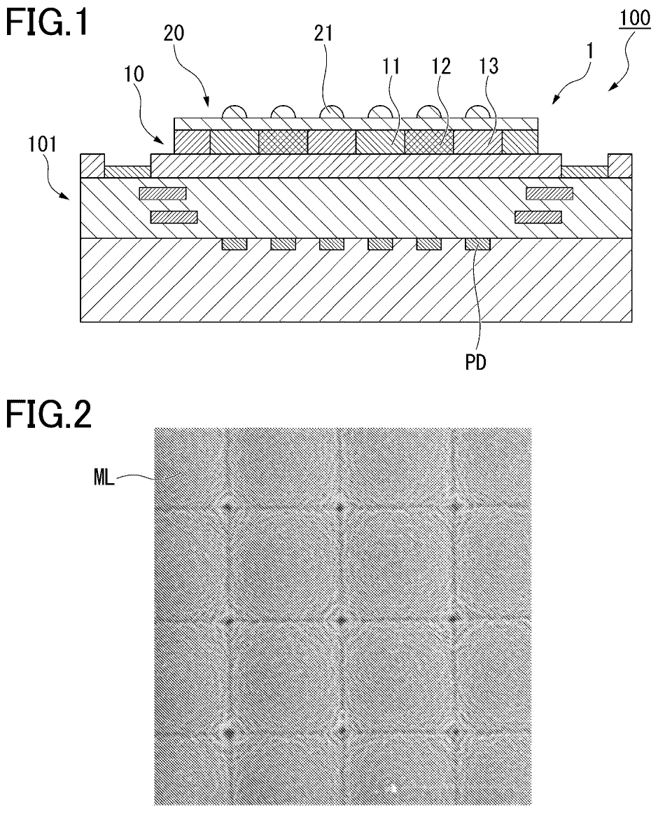

Embodiments will now be described with reference to the accompanying drawings, wherein like reference numerals designate corresponding or identical elements throughout the various drawings. Hereinafter, an embodiment of the present invention will be described with reference to FIGS. 1 to 7.

FIG. 1 is a schematic cross-sectional view of a solid-state imaging device 100 according to the present embodiment. The solid-state imaging device 100 includes a wafer substrate 101 that has multiple photoelectric conversion elements PD and an on-chip color filter 1 formed on the wafer substrate 101.

The on-chip color filter 1 has a filter part 10 including multiple kinds of color filters and a microlens part 20 formed on the filter part 10. The filter part 10 includes three kinds of color filters 11, 12, and 13.

The kinds, number, and distribution of colors of the filter part 10 can be determined as appropriate, and the filter part 10 may be a known filter part. For example, the filter part 10 may have a Bayer pattern using three colors of red, green, and blue. In a plan view of the solid-state imaging device 100, each color filter overlaps one of the photoelectric conversion elements PD.

The microlens part 20 has multiple microlenses 21. The microlenses 21 are positioned in a manner substantially identical to the color filters of the filter part 10. Each color filter overlaps one of the microlenses 21 in plan view of the solid-state imaging device 100.

In the solid-state imaging device 100 configured as described above, light incident on the microlenses 21 is guided to the photoelectric conversion elements PD through the corresponding color filters, to thereby provide an imaging function. The corresponding color filters here refer to the color filters overlapping the microlenses 21 in a plan view.

To improve the sensitivity of the solid-state imaging device 100, as large an amount of light as possible is guided to the microlenses 21. For this reason, the microlenses 21 of the microlens part 20 are formed using a technique such as thermal reflow or etch-back such that optical surfaces of microlenses ML are formed with substantially no gap therebetween in plan view as illustrated in FIG. 2. In the photograph of a conventional microlens part in FIG. 2, the microlenses are indicated with the sign ML, unlike the microlenses 21 in the present embodiment illustrated in the other drawings.

However, in high-definition solid-state imaging devices in which the diameter of each microlens or the dimension of a side of each color filter with the microlens positioned thereon is 1.2 μm or less, there is observed a phenomenon in which sufficient color purity cannot be obtained.

In an embodiment of the present invention, this phenomenon has been studied, and it has been found that petal flare caused by the microlens is a major cause.

Petal flare is flare generated in a petal form at intervals around the the optical axis of a microlens. It is considered that a petal flare is generated by interference of reflection light other than the reflection light generated in a normal direction on the optical surface of the microlens. Theoretically, petal flare may occur in conventional microlens arrays, but has not generally been recognized as a problem because the area of a unit pixel region is large enough to receive a large amount of light and the distance (pitch) from the region of the adjacent color filters is large. The region of the color filters refers to the region occupied by the color filters 11, 12, and 13 in plan view.

In an embodiment of the present invention, various methods for reducing petal flare have been studied. As a result, it has been found that it is effective to provide a specific amount of gap region without a microlens in plan view of the microlens part.

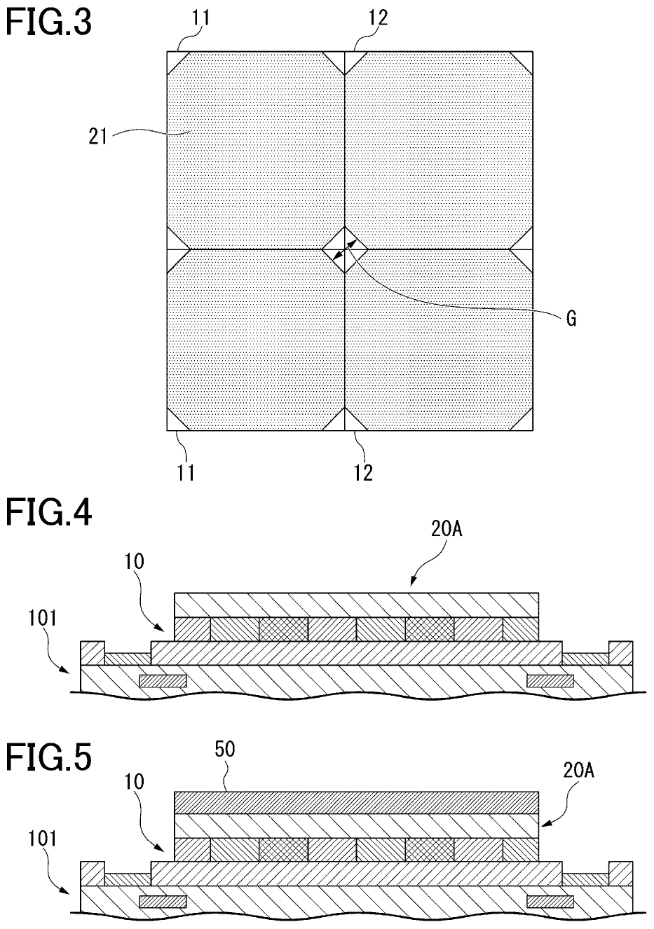

If the color filters have the shape of a rectangle such as a square in plan view, setting the diameter of microlenses to be substantially identical to the diagonal line of the regular square allows the microlenses to be positioned without a gap therebetween as illustrated in FIG. 2. If the diameter of the microlenses is decreased from this state, there is generated a gap region G in which no microlens is present at corners of the regular squares as illustrated in FIG. 3. Of the region of four color filters in plan view illustrated in FIG. 3, the left half is the region of the color filters 11, and the right half is the region of the color filters 12. However, the present invention is not limited to this example, and the regions of the color filters 11, 12, and 13 may be provided as appropriate in the region of the four color filters in plan view.

Gap regions first occur at corners as the diameter of the microlenses decreases, and then occur at sides between the corners with a further decrease in the diameter. In the following description, gaps occurring at the corners (the gap in the diagonal direction) will also be called “diagonal gaps”, and the gaps occurring at the sides (the gaps in the direction in which the sides extend) will also be called “horizontal gaps”. The diagonal gap has the shortest distance between two microlenses 21 adjacent to each other in the diagonal direction, and the horizontal gap has the shortest distance between two microlenses 21 adjacent to each other in the direction in which the sides of the regions of the color filters extend.

As the gap region increases, the area of the microlenses decreases in a plan view. Since decrease in the area of the microlenses in plan view leads to decrease in the amount of light gathered, it is difficult to suppress petal flare and maintain sensitivity in a compatible manner.

According to an embodiment of the present invention, a focus is on the refractive index of the material for forming the microlenses.

An example of a manufacturing process of the solid-state imaging device 100 will be described.

First, photoelectric conversion elements PD positioned in a two-dimensional matrix and a wafer substrate 101 having metallic wiring and the like are prepared. Then, color filters are formed in a desired formation on the wafer substrate 101 in correspondence with the regions of the photoelectric conversion elements PD, to thereby provide the filter part 10 on the wafer substrate 101. Forming the color filters in correspondence with the regions of the photoelectric conversion elements PD refers to forming the color filters such that the region of one color filter overlaps in a plan view the region occupied by a single photoelectric conversion element PD in a plan view.

Next, a first transparent layer 20A made of a non-photosensitive resin is formed on the filter part 10 as illustrated in FIG. 4. Then, a sacrificial layer 50 made of a photosensitive resin is formed on the first transparent layer 20A as illustrated in FIG. 5.

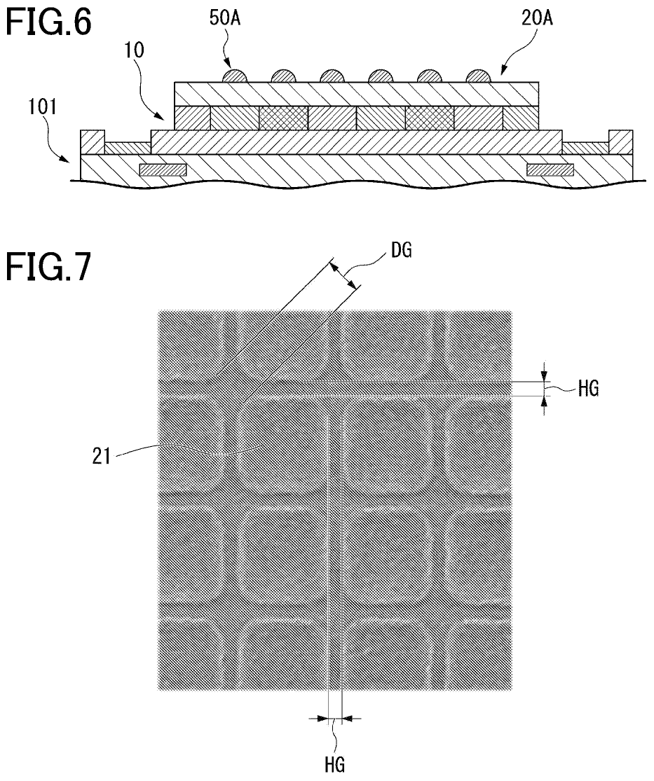

Subsequently, the sacrificial layer 50 is exposed and developed in a pattern matching the positions of the photoelectric conversion elements PD, and then is subjected to a thermal flow process under predetermined conditions. The pattern in correspondence with the positions of the photoelectric conversion elements PD refers to a pattern in which the sacrificial layer 50 overlaps the regions of the photoelectric conversion elements PD in a plan view. Accordingly, as illustrated in FIG. 6, a substantially hemispherical sacrificial pattern 50A is formed on the first transparent layer 20A at positions corresponding to the photoelectric conversion elements PD. The positions corresponding to the photoelectric conversion elements PD refer to the positions at which the sacrificial pattern 50A overlaps the photoelectric conversion elements PD in a plan view. The photoelectric conversion elements PD are not shown in FIGS. 4 to 6.

The shape of the sacrificial pattern 50A affects the shape of the microlenses to be formed later. Thus, the shape of the sacrificial pattern 50A is preferably formed such that the formed sacrificial pattern 50A has at least both the diagonal gaps and the horizontal gaps.

Then, the first transparent layer 20A and the sacrificial pattern 50A are subjected to dry etching. The dry etching removes the sacrificial pattern 50A and transfers the shape of the sacrificial pattern 50A to the first transparent layer 20A, so that lens-like structures are formed on the first transparent layer 20A. At this point in time, the lens-like structures are not in contact with each other and there are gap regions around the lens-like structures.

In the manufacture of a typical etch-back lens array, even after the transfer of the shape of the sacrificial pattern to the first transparent layer, the dry etching is continued until the horizontal gaps and the diagonal gaps are substantially eliminated. In the present embodiment, the dry etching is ended immediately after the completion of the transfer, or is ended after continuance for a period of time shorter than in usual etching. Accordingly, in the present embodiment, the formation of the lens-like structures is completed in the presence of both the horizontal gaps and the diagonal gaps.

As above, the microlens part 20 having the microlenses 21 is completed. After that, when the wafer substrate is cut into a predetermined size by dicing or the like, the solid-state imaging device 100 in the present embodiment is completed.

FIG. 7 illustrates a scanning electronic microscope (SEM) image of the microlens part actually produced in this manner. It can be seen that both diagonal gaps DG and horizontal gaps HG are provided between the microlenses 21 (two each of the microlenses 21).

Since the microlens part 20 has the diagonal gaps and the horizontal gaps provided between the microlenses 21 formed by dry etching, the occurrence of petal flare can be preferably suppressed even with high definition as described above. In an embodiment of the present invention, it has been confirmed that, if the region of a color filter is a square with a side length of 1.1 μm, providing diagonal gaps of about 0.40 to 0.75 μm and horizontal gaps of about 0.15 to 0.35 μm makes it possible to sufficiently suppress the occurrence of petal flare while maintaining sufficient sensitivity. When the foregoing numerical ranges are expressed by ratio to the side length of the region of the color filter, each diagonal gap is 38% or more and 70% or less, and each horizontal gap is 14% or more and 35% or less.

The fill factor that is the ratio of the area of the region occupied by the microlenses in plan view to the area of the region of the unit color filter in plan view is about 65% to 75%, which is a value range impossible to achieve (or a value range very difficult to achieve) in a general microlens array for use in an on-chip solid-state imaging device.

In the example illustrated in FIG. 7, the region of the color filter is a regular square with a side length of 0.93 μm, and the diagonal gaps DG and the horizontal gaps HG are respectively 43% and 18% of the side length of the region of the color filter, which are within the foregoing numerical ranges. The fill factor is a little under 70%, which is also within the foregoing numerical range.

The microlens array with the diagonal gaps and the horizontal gaps can be formed by development, exposure, and thermal flow of the sacrificial layer 50. However, in an embodiment of the present invention, it has been confirmed that, since there is an upper limit on the refractive index of the photosensitive resin for use in the sacrificial layer 50, it is not easy to maintain or improve the sensitivity while providing the diagonal gaps and horizontal gaps. On the other hand, some of the non-photosensitive resins for use in the first transparent layer 20A have a sufficient refractive index exceeding the upper limit of the photosensitive resin, for example, a refractive index n of 1.6 or more. Examples of such non-photosensitive resins with a high refractive index include polyamides, polyamide imides, polyether imides, norbornene-based resins, methacryl resins, isobutylene-maleic anhydride copolymer resins, cyclic olefin-based resins, polyvinyl alcohols, 3-methoxybutyl acetate, cyclopentanone, I-butyrolactone, propylene glycol monomethyl ether acetate, and acryl-based resins.

In the present embodiment, based on the foregoing findings, the first transparent layer 20A is formed from such a material with a high refractive index, and a lens array is formed by etch-back. This increases the refractive index of the microlens part 20 and improves the light-gathering rate. As a result, it is possible to suppress the occurrence of a petal flare and achieve high sensitivity in a compatible manner.

As above, an embodiment of the present invention has been described. However, the specific configuration of the present invention is not limited to this embodiment, and the present invention includes modifications and combinations of configurations within the scope of the present invention defined in the claims. Some modification examples will be described below, but they do not constitute all the modifications of the present invention, and any other modification can be made. Two or more of these modifications may be combined as appropriate.

The shape of the region of each color filter is not limited to the regular square described above and may be a rectangular shape or any other polygonal shape. If the shape of the region of the color filter has side lengths such as in the case of a rectangular shape, the thickness and the diagonal gaps are set with reference to the longest side length.

A solid-state imaging device in another embodiment of the present invention may have no color filter at some portions in plan view.

For example, if an embodiment of the present invention is applied to a solid-state imaging device in which some of the photoelectric conversion elements are used for focus adjustment, no color filter may be positioned in a region of the color filter part corresponding to the photoelectric conversion elements for use in focus adjustment. The region corresponding to the photoelectric conversion elements refers to the region overlapping the region occupied by the photoelectric conversion elements in a plan view.

A partition wall may be formed between color filters in order to prevent stray light. The partition wall may be a light-absorbing partition wall or may be a light-reflecting partition wall.

According to an embodiment of the present invention, a solid-state imaging device suppresses petal flare and achieves high sensitivity in a compatible manner.

There have been in widespread use single-plate solid-state imaging devices that are capable of obtaining color information on a target object using a color filter provided in the path of light incident on photoelectric conversion elements. The color filter has a planar formation of a colored transparent pattern having colors each of which selectively transmits light of a specific wavelength.

As solid-state imaging devices have become thinner, lighter, and higher in definition, there have been an increasing number of on-chip solid-state imaging devices in which a color filter is directly formed on the substrate on which photoelectric conversion elements are positioned.

Some on-chip solid-state imaging devices have microlenses positioned in order to efficiently guide light to photoelectric conversion elements (for example, refer to JP 2013-8777 A).

Digital image devices have advanced in image quality and downsizing. Accordingly, on-chip solid-state imaging devices are required to be higher in definition and are also required to have increased sensitivity in many cases.

In the course of studying how to obtain higher definition of solid-state imaging devices, a new issue of petal flare that has not been conventionally regarded as a problem has been recognized and solved.

A solid-state imaging device according to an embodiment of the present invention suppresses petal flare and achieves high sensitivity in a compatible manner.

One aspect of the present invention is a solid-state imaging device including a wafer substrate that has photoelectric conversion elements, a filter part that is formed on the wafer substrate and has multiple kinds of color filters positioned in correspondence with the photoelectric conversion elements, and a microlens part that is made of a non-photosensitive resin and has microlenses positioned in correspondence with the multiple kinds of color filters.

The microlenses are positioned with a gap between two microlenses out of the microlenses, which are adjacent to each other in a diagonal direction of a region having the multiple kinds of color filters that is square in a plan view and in which the multiple kinds of color filters is positioned, and with a gap between two microlenses out of the microlenses, which are adjacent to each other in a direction in which a side of the region of the multiple kinds of color filters extends.

According to an embodiment of the present invention, a solid-state imaging device suppresses petal flare and achieves high sensitivity in a compatible manner.

Obviously, numerous modifications and variations of the present invention are possible in light of the above teachings. It is therefore to be understood that within the scope of the appended claims, the invention may be practiced otherwise than as specifically described herein.

1. A solid-state imaging device, comprising:
a wafer substrate having a plurality of photoelectric conversion elements;
a filter part formed on the wafer substrate and having a plurality of color filters positioned in correspondence with the photoelectric conversion elements; and
a microlens part comprising a non-photosensitive resin and having a plurality of microlenses positioned in correspondence with the plurality of color filters,
wherein the plurality of color filters is positioned in a square region, and the plurality of microlenses is positioned such that two microlenses adjacent in a diagonal direction of the square region form a diagonal gap extending between the two microlenses adjacent in the diagonal direction of the square region and that two microlenses adjacent in a side direction of the square region form a horizontal gap extending between the two adjacent microlenses adjacent in the side direction of the square region.

2. The solid-state imaging device according to claim 1, wherein the plurality of microlenses is positioned such that the diagonal gap has a shortest distance in a range of 38% to 70% of a longest side of the square region and that the horizontal gap has a shortest distance in a range of 14% to 35% of the longest side of the square region.

3. The solid-state imaging device according to claim 1, wherein the microlens part has a refractive index of 1.6 or more.

4. The solid-state imaging device according to claim 1, wherein the plurality of color filters is formed such that the square region has a regular square shape having a side length of 1.2 vim or less.

5. The solid-state imaging device according to claim 2, wherein the microlens part has a refractive index of 1.6 or more.

6. The solid-state imaging device according to claim 2, wherein the plurality of color filters is formed such that the square region has a regular square shape having a side length of 1.2 or less.

7. The solid-state imaging device according to claim 3, wherein the plurality of color filters is formed such that the square region has a regular square shape having a side length of 1.2 μm or less.

8. The solid-state imaging device according to claim 5, wherein the plurality of color filters is formed such that the square region has a regular square shape having a side length of 1.2 μm or less.

9. A solid-state imaging device, comprising:
a wafer substrate having a plurality of photoelectric conversion elements;
a filter part formed on the wafer substrate and having a plurality of color filters positioned in correspondence with the photoelectric conversion elements; and
a microlens part comprising a non-photosensitive resin and having a plurality of microlenses positioned in correspondence with the plurality of color filters,
wherein the plurality of color filters is positioned in a square region, and the microlens part is formed such that the plurality of microlenses has a fill factor in a range of 65% to 75%, where the fill factor is a ratio of an area of a region of the microlenses to an area of the square region of the color filters.

10. The solid-state imaging device according to claim 9, wherein the microlens part has a refractive index of 1.6 or more.

11. The solid-state imaging device according to claim 9, wherein the plurality of color filters is formed such that the square region has a regular square shape having a side length of 1.2 μm or less.

12. The solid-state imaging device according to claim 10, wherein the plurality of color filters is formed such that the square region has a regular square shape having a side length of 1.2 μm or less.
